(19) United States
(12) Patent Application Publication
(10) Pub. No.: US 2024/0154594 A1
(43) Pub. Date: May 9, 2024

(54) FILTER CIRCUIT AND PLASMA PROCESSING APPARATUS

(71) Applicant: Tokyo Electron Limited, Tokyo (JP)

(72) Inventors: Yohei YAMAZAWA, Kurokawa-gun (JP); Naoki FUJIWARA, Kurokawa-gun (JP)

(21) Appl. No.: 18/412,676

(22) Filed: Jan. 15, 2024

Related U.S. Application Data
(63) Continuation of application No. PCT/JP2022/026443, filed on Jul. 1, 2022.

(30) Foreign Application Priority Data
Jul. 15, 2021 (JP) 2021-116814

(51) Int. Cl. H03H 7/01; H01J 37/32; H03H 7/075

(52) U.S. Cl. CPC H03H 7/0153; H01J 37/32027; H01J 37/32165; H01J 37/32174; H03H 7/075

(57) ABSTRACT

A filter circuit includes: a first filter provided in a wiring between a conductive member provided inside the plasma processing apparatus and a power supplier which supplies control power or DC power to the conductive member; and a second filter provided in a wiring between the first filter and the power supplier. The first filter includes a first coil connected in series to the wiring and having no core member. The second filter includes a second coil connected in series to the wiring between the first coil and the power supplier and having core members. The second coil includes a conducting wire arranged on a surface of at least one of the core members opposite to a surface of at least one of the core members facing a hollow inner cylinder, the at least one of the core members being arranged annularly around the inner cylinder.

### CROSS-REFERENCE TO RELATED APPLICATIONS

This application is a bypass continuation application of international application No. PCT/JP2022/026443 having an international filing date of Jul. 1, 2022 and designating the United States, the international application being based upon and claiming the benefit of priority from Japanese Patent Application No. 2021-116814, filed on Jul. 15, 2021, the entire contents of which are incorporated herein by reference.

### TECHNICAL FIELD

The present disclosure relates to a filter circuit and a plasma processing apparatus.

### BACKGROUND

For example, Patent Document 1 listed below discloses a filter unit provided between a heater and a heater power source. The filter unit includes an air-core solenoid coil provided on the heater side, and a core-containing coil provided between the air-core solenoid coil and the heater power source.

### PRIOR ART DOCUMENT

### Patent Document

Patent Document 1: Japanese Laid-Open Patent Publication No. 2014-229565

### SUMMARY

According to one embodiment of the present disclosure, there is provided a filter circuit provided in a plasma processing apparatus in which a substrate is processed by plasma generated using power of a first frequency and power of a second frequency lower than the first frequency. The filter circuit includes a first filter and a second filter. The first filter is provided in a wiring between a conductive member provided inside the plasma processing apparatus and a power supplier. The power supplier supplies control power, which is power of a third frequency lower than the second frequency or DC power, to the conductive member. The second filter is provided in the wiring between the first filter and the power supplier. Further, the first filter includes a first coil connected in series to the wiring and having no core member. Further, the second filter includes a second coil connected in series to the wiring between the first coil and the power supplier and having core members. The second coil includes a conducting wire arranged on a surface of at least one of the core members opposite to a surface of at least one of the core members facing a hollow inner cylinder, the at least one of the core members being arranged annularly around the hollow inner cylinder so as to surround an outer surface of the hollow inner cylinder.

### BRIEF DESCRIPTION OF DRAWINGS

The accompanying drawings, which are incorporated in and constitute a portion of the specification, illustrate embodiments of the present disclosure, and together with the general description given above and the detailed description of the embodiments given below, serve to explain the principles of the present disclosure.

FIG. 1 is a schematic sectional view showing an example of a plasma processing system according to an embodiment of the present disclosure.

FIG. 2 is a diagram showing an example of a circuit configuration of a filter circuit.

FIG. 3 is a diagram showing an example of a structure of the filter circuit.

FIG. 4 is a diagram showing an example of a structure of a first coil.

FIG. 5 is a diagram showing an example of a structure of a second coil.

FIG. 6 is a diagram showing an example of a structure of a partition plate.

FIGS. 7A and 7B are diagrams illustrating the size of an opening formed in the partition plate.

FIG. 8 is a diagram showing another example of a configuration near the filter circuit.

FIG. 9 is a diagram showing another example of the second coil.

FIG. 10 is a diagram showing a further example of the second coil.

FIG. 11 is a diagram showing another example of the structure of the filter circuit.

FIG. 12 is a diagram showing another example of a positional relationship between the second coil and the core member.

FIG. 13 is a diagram showing a further example of a structure of the filter circuit.

### DETAILED DESCRIPTION

Embodiments of the disclosed filter circuit and plasma processing apparatus will be described below in detail based on the drawings. Note that the disclosed filter circuit and plasma processing apparatus are not limited to the following embodiments. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

As a plasma processing apparatus has become more sophisticated in recent years, various devices have been provided in the plasma processing apparatus. As a result, the plasma processing apparatus tends to become larger. Therefore, it is desired to downsize the entire plasma processing apparatus by downsizing the devices provided in the plasma processing apparatus. The downsizing of a filter circuits is one example.

### [Configuration of Plasma Processing System 100]

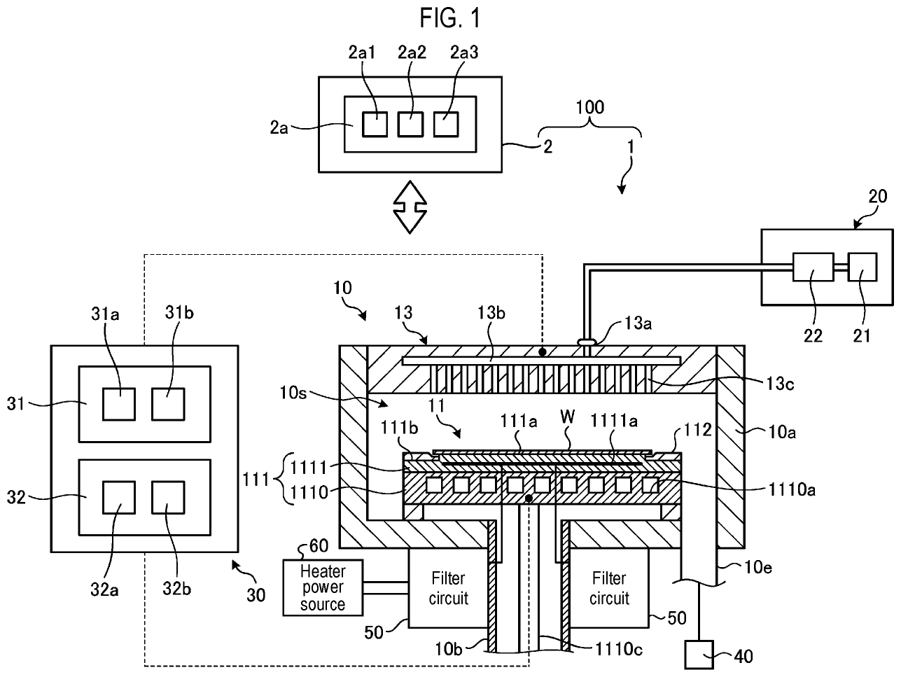

An example of the configuration of a plasma processing system 100 will be described below. FIG. 1 is a schematic sectional view showing an example of a plasma processing system 100 according to an embodiment of the present disclosure. The plasma processing system 100 includes a capacitively coupled plasma processing apparatus 1 and a controller 2. The plasma processing apparatus 1 includes a plasma processing chamber 10, a gas supplier 20, a power source 30, and an exhaust system 40. Further, the controller 2 includes a substrate supporter 11 and a gas introducer. The gas introducer is configured to introduce at least one processing gas into the plasma processing chamber 10. The gas introducer includes a shower head 13. The substrate supporter 11 is arranged within the plasma processing chamber 10. The shower head 13 is arranged above the substrate supporter 11. In one embodiment, the shower head 13 forms at least a portion of the ceiling of the plasma processing chamber 10.

The plasma processing chamber 10 has a plasma processing space 10s defined by the shower head 13, the side wall 10a of the plasma processing chamber 10 and the substrate supporter 11. The plasma processing chamber 10 has at least one gas supply port 13a for supplying at least one processing gas to the plasma processing space 10s, and at least one gas discharge port 10e for discharging the gas from the plasma processing space 10s. The side wall 10a is grounded. The shower head 13 and the substrate supporter 11 are electrically insulated from the housing of the plasma processing chamber 10.

The substrate supporter 11 includes a main body portion 111 and a ring assembly 112. The main body portion 111 has a substrate support surface 11a which is a central region for supporting a substrate W, and a ring support surface 111b which is an annular region for supporting the ring assembly 112. The substrate W is sometimes called a wafer. The ring support surface 111b of the main body portion 111 surrounds the substrate support surface 111a of the main body portion 111 in a plan view. The substrate W is arranged on the substrate support surface 111a of the main body portion 111, and the ring assembly 112 is arranged on the ring support surface 111b of the main body portion 111 so as to surround the substrate W on the substrate support surface 111a of the main body portion 111.

In one embodiment, the main body portion 111 includes a base 1110 and an electrostatic chuck 1111. The base 1110 includes a conductive member. The conductive member of the base 1110 functions as a lower electrode. The electrostatic chuck 1111 is arranged on the base 1110. The upper surface of the electrostatic chuck 1111 is a substrate support surface 111a.

An opening is formed at the bottom of the plasma processing chamber 10, and a hollow cylindrical member 10b is provided in the opening. The cylindrical member 10b is an example of an inner cylinder. In this embodiment, the cylindrical member 10b has a cylindrical shape, but the cylindrical member 10b does not need to have a cylindrical shape as long as it is a hollow cylinder. A power feeding rod 1110c is arranged inside the cylindrical member 10b. The power feeding rod 1110c is connected to the conductive member of the base 1110 and the power source 30. Although not shown in the drawings, a pipe for supplying a heat transfer gas to between the substrate W and the substrate support surface 111a, a lift pin drive mechanism, and the like are arranged inside the cylindrical member 10b. A filter circuit 50 is arranged outside the cylindrical member 10b so as to surround the outer surface of the cylindrical member 10b.

The filter circuit 50 is provided in a wiring that connects the heater power source 60 and the heater 1111a provided in the electrostatic chuck 1111. The filter circuit 50 attenuates high-frequency power flowing into the heater power source 60 from the heater 1111a. The heater power source 60 supplies a direct current or control power of 100 Hz or less to the heater 1111a. The heater 1111a is an example of a conductive member. The heater power source 60 is an example of a power supplier. The frequency of 100 Hz or less is an example of a third frequency.

The ring assembly 112 includes one or more annular members. At least one of the one or more annular members is an edge ring. Further, although not shown, the substrate supporter 11 may include a temperature control module configured to adjust at least one of the electrostatic chuck 1111, the ring assembly 112 and the substrate W to a target temperature. The temperature control module may include a flow path 1110a, a heat transfer medium, a heater 1111a, or a combination thereof. A heat transfer fluid such as brine or gas flows through the flow path 1110a. Further, the substrate supporter 11 may include a heat transfer gas supplier configured to supply a heat transfer gas to between the substrate W and the substrate support surface 111a.

The shower head 13 is configured to introduce at least one processing gas from the gas supplier 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. Further, the shower head 13 includes a conductive member. The conductive member of the shower head 13 functions as an upper electrode. In addition to the shower head 13, the gas introducer may include one or more side gas injectors (SGI) attached to one or more openings formed in the side wall 10a.

The gas supplier 20 may include at least one gas source 21 and at least one flow rate controller 22. In one embodiment, the gas supplier 20 is configured to supply at least one processing gas from the corresponding gas source 21 to the shower head 13 via the corresponding flow rate controller 22. The flow rate controller 22 may include, for example, a mass flow controller or a pressure-controlled flow rate controller. Additionally, the gas supplier 20 may include one or more flow rate modulation devices that modulate or pulse the flow rate of at least one processing gas.

The power source 30 includes an RF (Radio Frequency) power source 31 coupled to the plasma processing chamber 10 via at least one impedance matching circuit. The RF power source 31 is configured to provide at least one RF signal, such as a source RF signal or a bias RF signal, to the conductive member of the substrate supporter 11, the conductive member of the shower head 13, or both. For example, the RF power source 31 supplies at least one RF signal, such as a source RF signal or a bias RF signal, to the conductive member of the substrate supporter 11 via the power feeding rod 1110c. Thus, plasma is formed from at least one processing gas supplied to the plasma processing space 10s. Accordingly, the RF power source 31 may function as at least a portion of a plasma generator configured to generate plasma from one or more processing gases in the plasma processing chamber 10. Further, by supplying the bias RF signal to the conductive member of the substrate supporter 11, a bias potential is generated on the substrate W, and ion components in the formed plasma may be drawn into the substrate W.

In one embodiment, the RF power source 31 includes a first RF generator 31a and a second RF generator 31b. The first RF generator 31a is coupled to the conductive member of the substrate supporter 11, the conductive member of the shower head 13, or both via at least one impedance matching circuit, and is configured to generate a source RF signal for plasma generation. The source RF signal may also be referred to as source RF power. In one embodiment, the source RF signal has a frequency greater than 4 MHz. The source RF signal has a frequency within the range of 13 MHz to 150 MHz, for example. In this embodiment, the source RF signal has a frequency of 13 MHz. In one embodiment, the first RF generator 31a may be configured to generate multiple source RF signals having different frequencies. The generated one or more source RF signals are provided to the conductive member of the substrate supporter 11, the conductive member of the shower head 13, or both.

The second RF generator 31b is coupled to the conductive member of the substrate supporter 11 via at least one impedance matching circuit and is configured to generate a bias RF signal. The bias RF signal may also be referred to as bias RF power. In one embodiment, the bias RF signal has a lower frequency than the source RF signal. In one embodiment, the bias RF signal has a frequency greater than 100 Hz and less than or equal to 4 MHz. The bias RF signal has a frequency within the range of 400 kHz to 4 MHz, for example. In this embodiment, the bias RF signal has a frequency of 400 kHz. In one embodiment, the second RF generator 31b may be configured to generate multiple bias RF signals having different frequencies. The generated one or more bias RF signals are supplied to the conductive member of the substrate supporter 11 via the power feeding rod 1110c. In various embodiments, at least one of the source RF signal and the bias RF signal may be pulsed.

The power source 30 may also include a direct current (DC) power source 32 coupled to the plasma processing chamber 10. The DC power source 32 includes a first DC generator 32a and a second DC generator 32b. In one embodiment, the first DC generator 32a is connected to the conductive member of the substrate supporter 11 and is configured to generate a first DC signal. The generated first DC signal is applied to the conductive member of the substrate supporter 11. In another embodiment, the first DC signal may be applied to other electrodes, such as the electrode within the electrostatic chuck 1111. In one embodiment, the second DC generator 32b is connected to the conductive member of the shower head 13 and is configured to generate a second DC signal. The generated second DC signal is applied to the conductive member of the shower head 13. In various embodiments, at least one of the first and second DC signals may be pulsed. The first DC generator 32a and the second DC generator 32b may be provided in addition to the RF power source 31, or the first DC generator 32a may be provided in place of the second RF generator 31b.

The exhaust system 40 may be connected to, for example, the gas discharge port 10e provided at the bottom of the plasma processing chamber 10. The exhaust system 40 may include a pressure regulation valve and a vacuum pump. The pressure within the plasma processing space 10s is regulated by the pressure regulation valve. The vacuum pump may include a turbomolecular pump, a dry pump, or a combination thereof.

The controller 2 processes computer-executable instructions that cause the plasma processing apparatus 1 to perform various processes described in the present disclosure. The controller 2 may be configured to control each element of the plasma processing apparatus 1 to perform the various processes described herein. In one embodiment, a portion or the entirety of the controller 2 may be included in the plasma processing apparatus 1. The controller 2 may include, for example, a computer 2a. The computer 2a may include, for example, a processor 2al, a memory 2a2, and a communication interface 2a3. The processor 2al may be configured to perform various control operations based on programs stored in the memory 2a2. The processor 2al may include a CPU (Central Processing Unit). The memory 2a2 may include a RAM (Random Access Memory), a ROM (Read Only Memory), an HDD (Hard Disk Drive), an SSD (Solid State Drive), or a combination thereof. The communication interface 2a3 communicates with the plasma processing apparatus 1 via a communication line such as a LAN (Local Area Network) or the like.

### [Circuit Configuration of Filter Circuit 50]

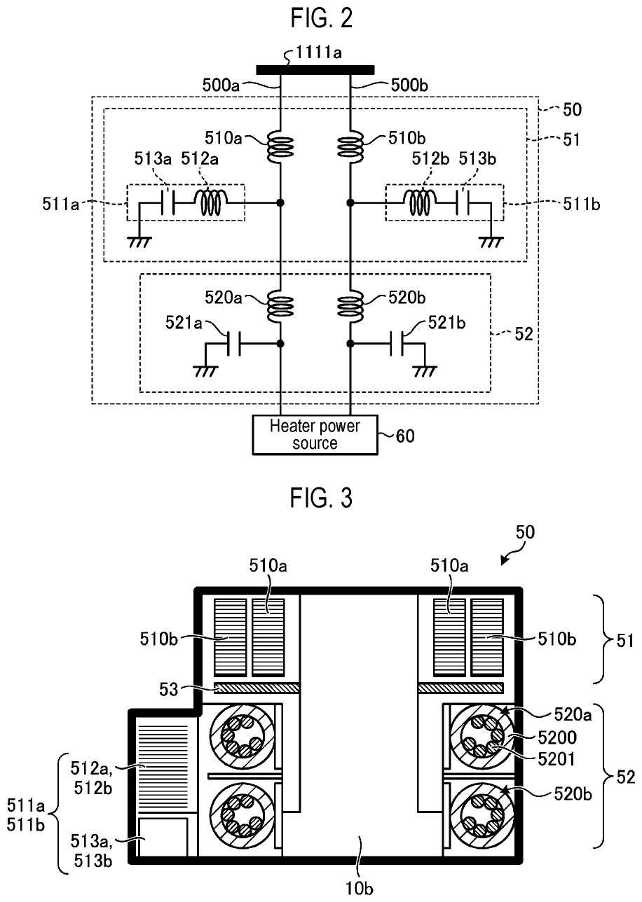

FIG. 2 is a diagram showing an example of a circuit configuration of the filter circuit 50. The heater 1111a and the heater power source 60 are connected via a wiring 500a and a wiring 500b. The filter circuit 50 is provided on the wiring 500a and the wiring 500b. The filter circuit 50 includes a first filter 51 and a second filter 52. The first filter 51 is provided in the wirings 500a and 500b between the heater 1111a and the heater power source 60. The first filter 51 suppresses the power of a first frequency among the power flowing into the heater power source 60 from the heater 1111a. The first frequency is, for example, higher than 4 MHz. In this embodiment, the first frequency is, for example, 13 MHz.

The first filter 51 includes a coil 510a and a series resonant circuit 511a connected to the wiring 500a. Further, the first filter 51 includes a coil 510b and a series resonant circuit 511b connected to the wiring 500b. The coils 510a and 510b are air-core coils that do not have a core member (that is, the core member is air or vacuum). Thus, the heat generation in the coil 510 may be suppressed. The coils 510a and 510b are examples of first coils. The coils 510a and 510b may be provided with a core member having a magnetic permeability of less than 10, such as a resin material including PTFE (polytetrafluoroethylene).

The series resonant circuit 511a is connected between the node between the coil 510a and the second filter 52 and the ground. The series resonant circuit 511a includes a coil 512a and a capacitor 513a. The coil 512a and the capacitor 513a are connected in series. In the series resonant circuit 511a, the constants of the coil 512a and the capacitor 513a are selected so that the resonant frequency of the series resonant circuit 511a is near the first frequency. The series resonant circuit 511b is connected between the wiring between the coil 510b and the second filter 52 and the ground. The series resonant circuit 511b includes a coil 512b and a capacitor 513b. The coil 512b and the capacitor 513b are connected in series. In the series resonant circuit 511b, the constants of the coil 512b and the capacitor 513b are selected so that the resonant frequency of the series resonant circuit 511b is near the first frequency.

Just like the coils 510a and 512b, the coils 512a and 512b are, for example, air-core coils without a core member. In this embodiment, the inductance of the coils 512a and 512b is, for example, 6 μH. Further, in this embodiment, the capacitance of the capacitors 513a and 513b is 500 pF or less, for example, 25 pF. As a result, the resonant frequency of the series resonant circuits 511a and 511b is approximately 13 MHz. The capacitors 513a and 513b are preferably, for example, vacuum capacitors in order to suppress fluctuations in constants due to the influence of heat.

The second filter 52 includes a coil 520a, a capacitor 521a, a coil 520b, and a capacitor 521b. One end of the coil 520a is connected to a node between the coil 510a and the series resonant circuit 511a, and the other end of the coil 520a is connected to the heater power source 60. The capacitor 521a is connected between the node between coil 520a and the heater power source 60 and the ground. One end of the coil 520b is connected to a node between the coil 510b and the series resonant circuit 511b, and the other end of the coil 520b is connected to the heater power source 60. The capacitor 521b is connected between the node between the coil 520b and the heater power source 60 and the ground. The second filter 52 suppresses the power of a second frequency among the power flowing into the heater power source 60 from the heater 1111a. The second frequency is, for example, higher than 100 Hz and lower than 4 MHz. In this embodiment, the second frequency is, for example, 400 kHz.

Although the first filter 51 in this embodiment includes the series resonant circuit 511a and the series resonant circuit 511b, the disclosed technique is not limited thereto. For example, instead of the series resonant circuit 511a and the series resonant circuit 511b, a capacitor (not shown) adjusted to have a low impedance for the first frequency may be provided. This capacitor (not shown) is preferably, for example, a vacuum capacitor in order to suppress fluctuations in constants due to the influence of heat.

The coils 520a and 520b are cored coils having a core member with a magnetic permeability of 10 or more. The coils 520a and 520b are examples of second coils. In this embodiment, the inductance of the coils 520a and 520b is, for example, 10 mH. Examples of the core member having a magnetic permeability of 10 or more include ferrite, dust material, permalloy, cobalt-based amorphous material, and the like. In this embodiment, the capacitors 521a and 521b are provided at positions spaced apart from the heater 1111a, so that they are less susceptible to the influence of heat from the heater 1111a. Therefore, as the capacitors 521a and 521b, ceramic capacitors or the like, which are cheaper than vacuum capacitors, may be used.

In this embodiment, the capacitance of the capacitors 521a and 521b is, for example, 2000 pF. Further, in this embodiment, the parasitic capacitance of the wiring between the heater 1111a and the first filter 51, the wiring between the first filter 51 and the second filter 52, and the wiring between the second filter 52 and the heater power source 60 is adjusted to 500 pF or less. For example, by inserting a spacer such as a resin between the wiring and the ground to increase the distance between the wiring and the ground, the parasitic capacitance between the wiring and the ground may be adjusted to 500 pF or less.

### [Structure of Filter Circuit 50]

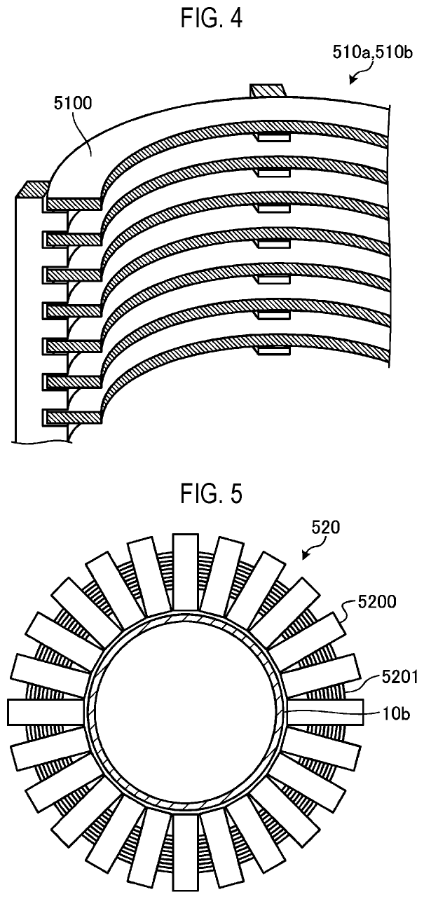

FIG. 3 is a diagram showing an example of the structure of the filter circuit 50. The coils 510a and 510b of the first filter 51 are arranged annularly around the cylindrical member 10b so as to surround the cylindrical member 10b. In the example of FIG. 3, the coil 510a is arranged closer to the cylindrical member 10b than the coil 510b. The coil 510b is arranged around the coil 510a so as to surround the coil 510a. In this embodiment, the conducting wire 5100 constituting the coils 510a and 510b is formed into a plate shape, for example, as shown in FIG. 4. This allows the number of turns of the coil to be increased even in a narrow space.

The coils 520a and 520b of the second filter 52 are arranged annularly around the cylindrical member 10b so as to surround the cylindrical member 10b. In the example of FIG. 3, the coil 520a is arranged closer to the first filter 51 than the coil 520b. The coils 520a and 520b have a core member 5200 and a conducting wire 5201. The core member 5200 is annularly formed of a material such as ferrite having a magnetic permeability of 10 or more. In this embodiment, the conducting wire 5201 forming the coils 520a and 520b is arranged within the core member 5200. In this embodiment, the core member 5200 is formed in a circular ring shape. However, as long as the core member 5200 has a ring shape, the outer shape of the core member 5200 may be a shape other than the circular ring shape, such as a rectangular ring shape or the like.

In this embodiment, the coils 510a and 510b of the first filter 51 and the coils 520a and 520b of the second filter 52 are arranged annularly around the cylindrical member 10b so that their central axes coincide. This makes it possible to downsize the filter circuit 50.

Further, in this embodiment, for example, as shown in FIG. 5, a plurality of core members 5200 are arranged in a ring shape around the cylindrical member 10b so as to surround the outer surface of the cylindrical member 10b. In the example of FIG. 5, the respective core members 5200 are annularly arranged around the cylindrical member 10b in a direction in which the central axes of the core members 5200 intersect the extension direction of the cylindrical member 10b (for example, in a perpendicular direction). The conducting wire 5201 is arranged inside the plurality of core members 5200 arranged annularly around the cylindrical member 10b. That is, the conducting wire 5201 is arranged on the surfaces of the core members 5200 opposite to the surfaces thereof facing the cylindrical member 10b. Further, in this embodiment, the conducting wire 5201 is not arranged between the core members 5200 and the cylindrical member 10b.

Here, for example, a coil having a structure in which a conducting wire is wound along an annular toroidal core so as to alternately pass inside and outside the opening of the annular toroidal core, such as the toroidal coil of Patent Document 1, is considered. In the coil wound in this manner, the conducting wire is located inside and outside the toroidal core. Therefore, when arranging the toroidal coil, it is necessary to provide a gap between the conducting wire and the structure outside the toroidal coil. In particular, if a conductor connected to the ground exists around the toroidal coil, it is necessary to provide a wide gap between the conductor and the conducting wire of the toroidal coil in order to reduce the parasitic capacitance between the conductor and the toroidal coil. Similarly, if a conductor such as the cylindrical member 10b or the like connected to the ground exists inside the toroidal coil, it is necessary to provide a wide gap between the conductor and the conducting wire of the toroidal coil in order to reduce the parasitic capacitance between the conductor and the toroidal coil. Therefore, when using the toroidal coil, it is difficult to downsize the filter circuit.

On the other hand, in this embodiment, the conducting wire 5201 constituting the coil of the second filter 52 is arranged inside the annular core member 5200. Therefore, when arranging the coil of the second filter 52, the core member 5200 is arranged in the gap between the conducting wire 5201 and the structure around the coil. Therefore, a gap may be easily formed between the conducting wire 5201 and the structure around the coil. Further, since the core member 5200 is arranged in the gap between the conducting wire 5201 and the structure around the coil, it is possible to efficiently use the gap between the conducting wire 5201 and the structure around the coil. Accordingly, the second filter 52 may be made smaller than the toroidal core of Patent Document 1, which makes it possible to downsize the filter circuit 50 and the plasma processing apparatus.

Further, in the example of FIG. 5, the adjacent core members 5200 are arranged annularly around the cylindrical member 10b with an interval left therebetween. As a result, the heat generated in the coil 520 and the conducting wire 5201 is dissipated from between the adjacent core members 5200. Accordingly, it is possible to efficiently radiate heat from the coil 520 and the conducting wire 5201.

Returning to FIG. 3, the description will be continued. A partition plate 53 formed of a conductive member is arranged between the coils 510a and 510b of the first filter 51 and the coils 520a and 520b of the second filter 52. The partition plate 53 is grounded. The partition plate 53 suppresses magnetic coupling between the coils 510a and 510b of the first filter 51 and the coils 520a and 520b of the second filter 52.

In this regard, the partition plate 53 needs to pass through the wiring for connecting the coil 510a and the coil 520a and the wiring for connecting the coil 510b and the coil 520b. However, if an opening for passing these wirings is provided in the partition plate 53, some of the magnetic field lines generated from the coils included in the first filter 51 and the second filter 52 may pass through the gap between the opening of the partition plate 53 and the wiring. This may strengthen the magnetic coupling between the coil included in the first filter 51 and the coil included in the second filter 52.

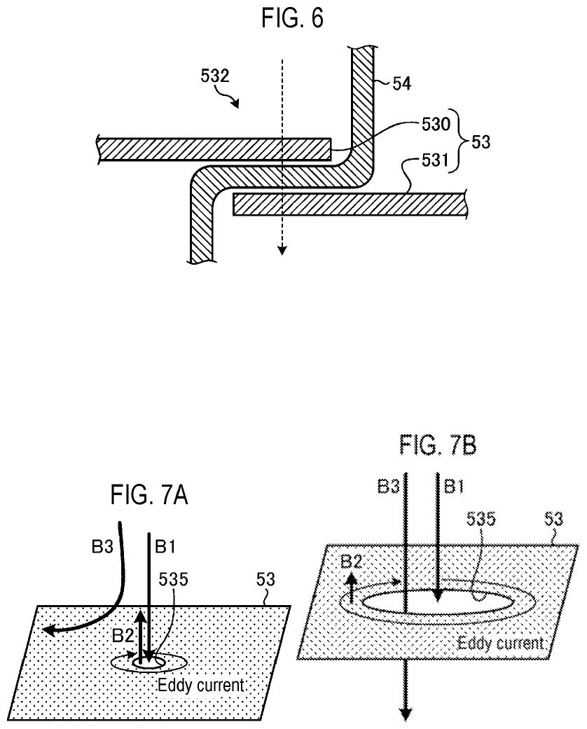

Therefore, in this embodiment, as shown in FIG. 6, for example, a first shielding member 530 and a second shielding member 531 are provided in a wiring region 532 of the partition plate 53 through which the wiring 54 passes. The wiring 54 is a wiring that connects the coil included in the first filter 51 and the coil included in the second filter 52. A gap in which the wiring 54 is arranged is formed between the first shielding member 530 and the second shielding member 531. In addition, the first shielding member 530 and the second shielding member 531 are arranged to shield a straight path (the direction of the broken line arrow in FIG. 6) extending from the coil included in the first filter 51 to the coil included in the second filter 52. As a result, it is possible to prevent some of the magnetic field lines generated from the coils included in the first filter 51 and the second filter 52 from passing through the gap between the opening of the partition plate 53 and the wiring. Accordingly, it is possible to suppress magnetic coupling between the coil included in the first filter 51 and the coil included in the second filter 52. If the voltage applied to the wiring 54 is very high, there is a risk that abnormal discharge may occur between the wiring 54 and the first shielding member 530 and the second shielding member 531. Therefore, it is desirable that the wiring 54 arranged in the gap between the first shielding member 530 and the second shielding member 531 does not come into contact with either the first shielding member 530 or the second shielding member 531. In particular, when a high voltage of about 1 kV is applied to the wiring 54, it is desirable that the distance between the first shielding member 530 and the wiring 54 and the distance between the second shielding member 531 and the wiring 54 are approximately 1 mm. When a high voltage of about 10 kV is applied to the wiring 54, it is desirable that the distance between the first shielding member 530 and the wiring 54 and the distance between the second shielding member 531 and the wiring 54 are approximately 10 mm. Although air is present between the first shielding member 530 and the wiring 54 and between the second shielding member 531 and the wiring 54, an insulator such as a porcelain insulator or the like may be present.

Further, when a current flows through the coil included in the first filter 51 and the coil included in the second filter 52, these coils generate heat. Further, when a current flows through the coil included in the second filter 52, the core member 5200 generates heat. Thus, heat dissipation from the first filter 51 and the second filter 52 is important. Therefore, in this embodiment, a plurality of through-holes 535 are formed in the partition plate 53 in order to promote the circulation of air within the filter circuit 50.

When the through-holes 535 are formed in the partition plate 53, an eddy current is generated around the through-holes 535 due to the magnetic field lines B1 passing through the through-holes 535, for example, as shown in FIG. 7A. Then, due to the generated eddy current, magnetic field lines B2 are generated in the opposite direction to the magnetic field lines B1. When the openings of the through-holes 535 are sufficiently small, the magnitude of the magnetic field lines B2 generated by the eddy current becomes equal to the magnetic field lines B1. Therefore, the magnetic field lines B3, which are a combination of the magnetic field lines B1 and the magnetic field lines B2, do not pass through the through-holes 535.

On the other hand, when the openings of the through-holes 535 are large, the magnitude of the magnetic field lines B2 generated by the eddy current is smaller than the magnitude of the magnetic field lines B1. Therefore, for example, as shown in FIG. 7B, the magnetic field lines B3, which are a combination of the magnetic field lines B1 and the magnetic field lines B2, pass through the through-holes 535. Therefore, it is desirable that the size of the openings of the through-holes 535 formed in the partition plate 53 is such a size that does not allow the magnetic field lines to pass through. For example, when the openings of the through-holes 535 are circular, the diameter of the openings is preferably 4 mm or less for the magnetic field lines of electromagnetic waves having a frequency of less than 50 MHz.

One embodiment has been described above. As described above, the filter circuit 50 according to this embodiment, which is provided in the plasma processing apparatus 1 that processes the substrate W using the plasma generated using the power of a first frequency and the power of a second frequency lower than the first frequency, includes the first filter 51 and the second filter 52. The first filter 51 is provided in the wiring between the heater 1111a provided inside the plasma processing apparatus 1 and the heater power source 60. The heater power source 60 supplies control power, which is power of a third frequency lower than the second frequency or DC power, to the heater 1111a. The second filter 52 is provided in the wiring between the first filter 51 and the heater power source 60. Further, the first filter 51 includes coils 510a and 510b connected in series to the wiring between the substrate support surface 111a and the second filter 52 and having no core member. In addition, the second filter 52 includes the coil 520a connected in series to the wiring between the coil 510a and the heater power source 60 and having the core member 5200, and the coil 520b connected in series to the wiring between the coil 510b and the heater power source 60 and having the core member 5200. Further, the conducting wires included in the coils 520a and 520b are arranged on the surface of at least one core member 5200 opposite to the surface of the core member 520 facing the hollow cylindrical member 10b, wherein the core member 5200 is arranged annularly around the cylindrical member 10b so as to surround the outer surface of the cylindrical member 10b. Accordingly, it is possible to downsize the filter circuit 50 and the plasma processing apparatus 1.

Further, in this embodiment, a plurality of core members 5200 are annularly arranged around the cylindrical member 10b. Each of the core members 5200 is annular, and each of the second filters 5200 is annularly arranged around the cylindrical member 10b in a direction in which the central axes of the core members 5200 intersect the extension direction of the cylindrical member 10b. Further, the conducting wires constituting the coil 520 are arranged within each of the core members 5200. Accordingly, it is possible to downsize the second filter 52.

Further, in this embodiment, the adjacent core members 5200 are annularly arranged around the cylindrical member 10b with an interval left therebetween. Accordingly, it is possible to efficiently dissipate heat from the core members 5200 and the conducting wires 5201.

In addition, the filter circuit 50 according to this embodiment further includes the partition plate 53 formed of a conductive member and provided between the coil included in the first filter 51 and the coil included in the second filter 52. The partition plate 53 is grounded. Accordingly, the first filter 51 and the second filter 52 may be arranged close to each other while suppressing magnetic coupling between the coil included in the first filter 51 and the coil included in the second filter 52.

Further, in this embodiment, the second filter 52 is provided with a wiring region 532 through which the wiring for connecting the coil included in the first filter 51 and the coil included in the second filter 52 passes. The first shielding member 530 and the second shielding member 531 are arranged in the wiring region 532 so that a straight path extending from the coil included in the first filter 51 to the coil included in the second filter 52 is not formed. Accordingly, the first filter 51 and the second filter 52 may be arranged close to each other while suppressing magnetic coupling between the coil included in the first filter 51 and the coil included in the second filter 52.

Further, in this embodiment, the partition plate 53 is formed with a plurality of through-holes 535 each having an opening of a predetermined size or less. Each opening of the partition plate 53 is circular, and the diameter of the opening is, for example, 4 mm or less. Accordingly, the circulation of air within the filter circuit 50 may be promoted while suppressing the magnetic field lines passing through the through-holes 535.

Further, in this embodiment, the coil included in the first filter 51 and the coil included in the second filter 52 are arranged so that the central axes thereof coincide. Accordingly, it is possible to downsize the filter circuit 50 and the plasma processing apparatus 1.

Further, in this embodiment, the first frequency is higher than 4 MHz. Further, the second frequency is higher than 100 Hz and equal to or lower than 4 MHz. Further, the third frequency is 100 Hz or less. Accordingly, the plasma processing apparatus 1 may perform plasma processing by using a source RF signal having a frequency higher than 4 MHz and a bias RF signal having a frequency higher than 100 Hz and equal to or lower than 4 MHz. In addition, the heater power source 60 may control the amount of heat generated by the heater 1111a using a direct current or control power of 100 Hz or less.

Further, in this embodiment, the first filter 51 further includes the series resonant circuits 511a and 511b connected between the wiring between the heater 1111a and the second filter 52 and the ground and having a coil and a vacuum capacitor connected in series. Accordingly, it is possible to suppress the fluctuations in the constants of the series resonant circuits 511a and 511b due to the influence of heat. Instead of the series resonant circuits 511a and 511b, a capacitor adjusted to have a low impedance with respect to the first frequency may be provided.

Further, in this embodiment, the core members 5200 are made of ferrite, dust material, permalloy, or cobalt-based amorphous material. Accordingly, it is possible to downsize the second filter 52.

Further, the plasma processing apparatus 1 according to the present embodiment includes the plasma processing chamber 10 configured to process a substrate W by the plasma generated using power of a first frequency and power of a second frequency lower than the first frequency, the heater 1111a provided in the plasma processing chamber 10, and the filter circuit 50. The filter circuit 50 includes the first filter 51 and the second filter 52. The first filter 51 is provided in the wiring between the heater 1111a and the heater power source 60. The heater power source 60 supplies control power, which is power of a third frequency lower than the second frequency or DC power, to the heater 1111a. The second filter 52 is provided in the wiring between the first filter 51 and the heater power source 60. Further, the first filter 51 includes coils 510a and 510b connected in series to the wiring between the substrate support surface 111a and the second filter 52 and having no core member. In addition, the second filter 52 includes the coil 520a connected in series to the wiring between the coil 510a and the heater power source 60 and having the core member 5200, and the coil 520b connected in series to the wiring between the coil 510b and the heater power source 60 and having the core member 5200. Further, the conducting wires included in the coils 520a and 520b are arranged on the surface of at least one core member 5200 opposite to the surface of the core member 5200 facing the hollow cylindrical member 10b, wherein the core member 5200 is arranged annularly around the cylindrical member 10b so as to surround the outer surface of the cylindrical member 10b. Accordingly, it is possible to downsize the plasma processing apparatus 1.

### [Others]

The technique disclosed in this application is not limited to the embodiment described above, and may be modified in many ways within the scope of the gist thereof.

For example, in the embodiment described above, the plasma processing apparatus 1 in which one heater 1111a is provided in the electrostatic chuck 1111 has been described. However, the disclosed technique is not limited thereto. For example, a plurality of heaters 1111a may be provided within the electrostatic chuck 1111. In this case, one first filter 51 and one second filter 52 are provided for each heater 1111a. The coil 510a and the coil 510b, which are provided one for each heater 1111a, are arranged, for example, concentrically about the cylindrical member 10b in the region of the first filter 51 in FIG. 3. Similarly, the coils 520a and 520b, which are provided one for each heater 1111a, are arranged, for example, concentrically about the cylindrical member 10b in the region of the second filter 52 in FIG. 3.

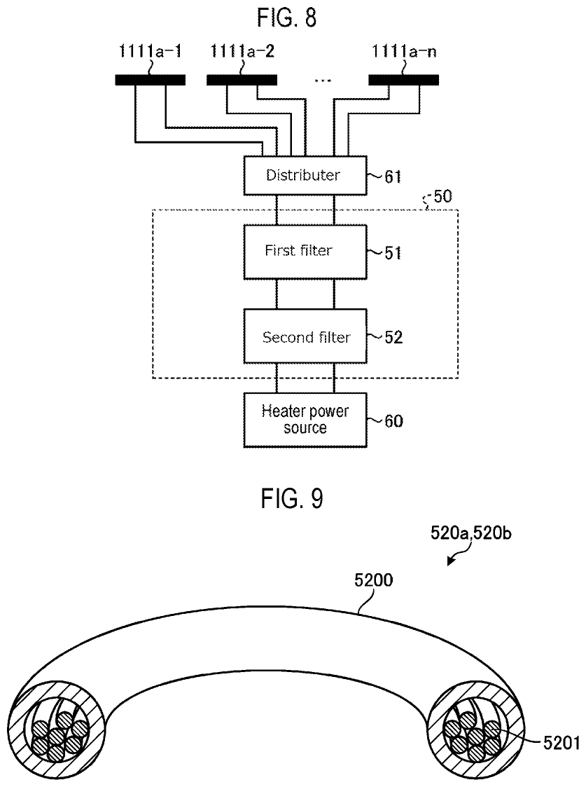

Alternatively, for example, as shown in FIG. 8, a distributer 61 may be provided between the plurality of heaters 1111a and the filter circuit 50. The distributer 61 individually supplies control power to each of the plurality of heaters 1111a. Accordingly, it is possible to downsize the filter circuit 50 and downsize the plasma processing apparatus 1.

Further, in the embodiment described above, the plurality of annular core members 5200 are arranged around the cylindrical member 10b, and the conducting wire 5201 constituting the coil included in the second filter 52 is arranged in each core member 5200. However, the disclosed technique is not limited thereto. As another form, the core member 5200 may be formed into a tubular shape, for example, as shown in FIG. 9. The core member 5200 is annularly arranged around the cylindrical member 10b with the central axis of the core member 5200 oriented in a direction intersecting the extension direction of the cylindrical member 10b. The conducting wire 5201 is disposed within the tubular core member 5200 along the direction in which the core member 5200 extends. Accordingly, the magnetic flux generated within the core member 5200 by the conducting wire 5201 may be suppressed from becoming saturated within the core member 5200.

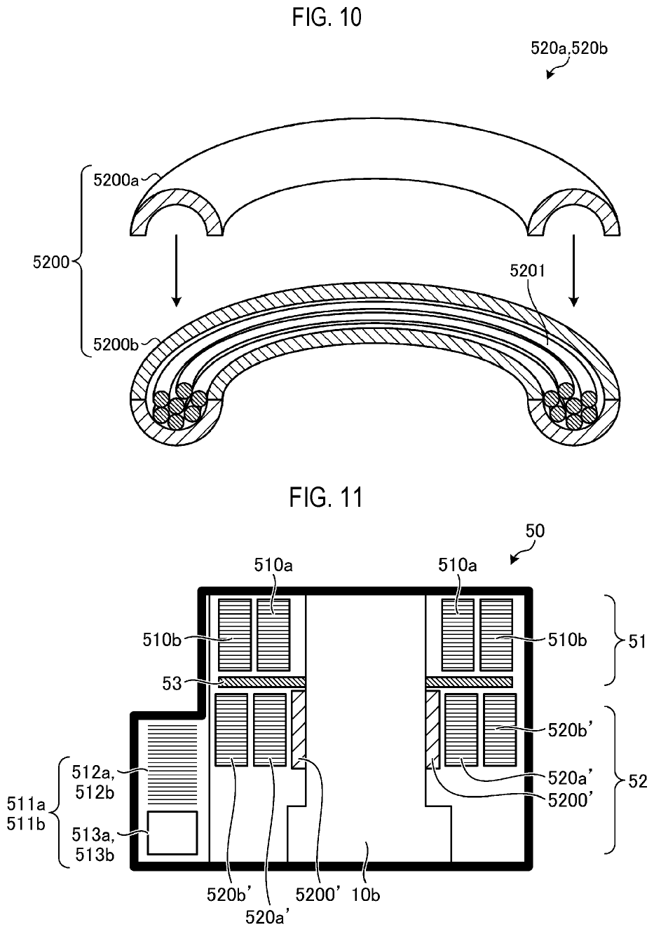

The core member 5200 illustrated in FIG. 9 may be divisible into two portions 5200a and 5200b along the extension direction (central axis) of the core member 5200, for example, as shown in FIG. 10. Accordingly, by arranging the conducting wire 5201 on one portion 5200b and then combining the other portion 5200a with the one portion 5200a, it is possible to easily realize the coils 520a and 520b in the state illustrated in FIG. 9.

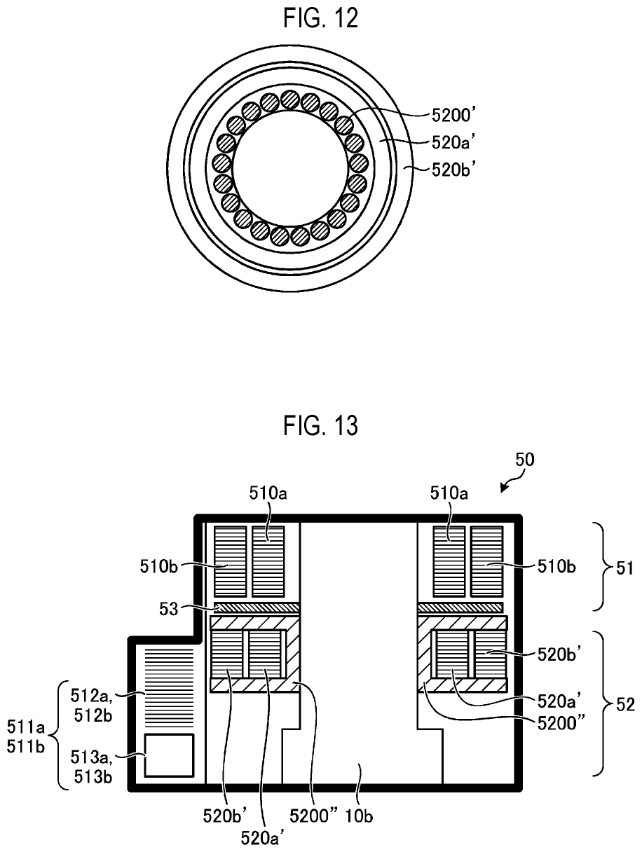

Further, in the embodiment described above, the plurality of annular core members 5200 are arranged around the cylindrical member 10b, and the conductive wire 5201 constituting the coil included in the second filter 52 is arranged in each core member 5200. However, the disclosed technique is not limited thereto. For example, as shown in FIGS. 11 and 12, a plurality of rod-shaped core members 5200′ may be arranged around the cylindrical member 10b. FIG. 12 shows an example of the positional relationship between the core members 5200′ and the coils 520a′ and 520b′ when viewed along the extension direction of the cylindrical member 10b. Each core member 5200′ is arranged annularly around the cylindrical member 10b so that the longitudinal direction thereof is oriented along the extension direction of the cylindrical member 10b. In this case, the coils 520a′ and 520b′ of the second filter 52 are arranged annularly around the cylindrical member 10b and the plurality of core members 5200′ so as to surround the cylindrical member 10b and the plurality of core members 5200′. In the example of FIGS. 11 and 12, the coils 520a′ and 520b′ of the second filter 52 may also be formed of plate-shaped wirings, for example, as shown in FIG. 4. Accordingly, it is possible to downsize the second filter 52.

Further, the core member 5200″ provided in the second filter 52 may have a hollow bobbin-like shape, for example, as shown in FIG. 13. By virtue of this shape, the second filter 52 may be downsized while suppressing saturation of the magnetic flux at the core member 5200″.

Further, in the embodiment described above, the control power from the heater power source 60, which is an example of the power supplier, is supplied to the heater 1111a, which is an example of the conductive member. However, the conductive member to which the control power is supplied is not limited thereto. For example, the power controller may supply the control power to conductive members other than the heater 1111a provided in the plasma processing apparatus 1. Examples of the conductive members other than the heater 1111a include the conductive member of the substrate supporter 11 to which the power of a first frequency and the power of a second frequency are supplied, the conductive member of the shower head 13, the ring assembly 112, and the like.

Further, in the embodiment described above, the plasma processing apparatus 1 using the capacitively coupled plasma (CCP) as a plasma source has been described as an example. However, the plasma source is not limited thereto. Examples of plasma sources other than the capacitively coupled plasma include inductively coupled plasma (ICP), and the like.

According to various aspects and embodiments of the present disclosure, it is possible to downsize a filter circuit and a plasma processing apparatus.

The embodiments disclosed herein should be considered to be exemplary in all respects and not limitative. Indeed, the embodiments described above may be implemented in various forms. Further, the above-described embodiments may be omitted, replaced, or modified in various forms without departing from the scope and spirit of the appended claims.

### (Supplementary Note 1)

A filter circuit provided in a plasma processing apparatus in which a substrate is processed by plasma generated using power of a first frequency and power of a second frequency lower than the first frequency, includes:
a first filter provided in a wiring between a conductive member provided inside the plasma processing apparatus and a power supplier configured to supply control power, which is power of a third frequency lower than the second frequency or DC power, to the conductive member; and
a second filter provided in the wiring between the first filter and the power supplier,
wherein the first filter includes a first coil connected in series to the wiring and having no core member,
the second filter includes a second coil connected in series to the wiring between the first coil and the power supplier and having core members, and
the second coil includes a conducting wire arranged on a surface of at least one of the core members opposite to a surface of at least one of the core members facing a hollow inner cylinder, the at least one of the core members being arranged annularly around the hollow inner cylinder so as to surround an outer surface of the hollow inner cylinder.

### (Supplementary Note 2)

In the filter circuit of Supplementary Note 1 above, the core members are annularly arranged around the hollow inner cylinder,
each of the core members is annular,
each of the core members is annularly arranged around the hollow inner cylinder in a direction in which central axes of the core members intersect an extension direction of the hollow inner cylinder, and
the conducting wire constituting the second coil is arranged inside each of the core members.

### (Supplementary Note 3)

In the filter circuit of Supplementary Note 2 above, the core members adjacent to each other are annularly arranged around the hollow inner cylinder with an interval left therebetween.

### (Supplementary Note 4)

In the filter circuit of Supplementary Note 1 above, each of the core members is tubular,
each of the core members is annularly arranged around the hollow inner cylinder in a direction in which central axes of the core members intersect an extension direction of the hollow inner cylinder, and
the wiring between the first filter and the power supplier is arranged inside each of the core members.

### (Supplementary Note 5)

In the filter circuit of Supplementary Note 4 above, each of the core members is separable on a plane extending along the central axes of the core members.

### (Supplementary Note 6)

In the filter circuit of Supplementary Note 1 above, the core members are annularly arranged around the hollow inner cylinder,
each of the core members is rod-shaped, and
each of the core members is arranged annularly around the hollow inner cylinder in a direction in which the longitudinal direction of the core members is oriented to extend along an extension direction of the hollow inner cylinder.

### (Supplementary Note 7)

The filter circuit of any one of Supplementary Notes 1 to 6 above further includes:
a partition plate formed of a conductive member and provided between the first coil and the second coil,
wherein the partition plate is grounded.

### (Supplementary Note 8)

In the filter circuit of Supplementary Note 7 above, the partition plate is provided with a wiring region through which a wiring for connecting the first coil and the second coil passes, and
a shielding member is provided in the wiring region so that a straight path extending from the first coil to the second coil is not formed.

### (Supplementary Note 9)

In the filter circuit of Supplementary Note 7 or 8 above, a plurality of through-holes each having an opening of a predetermined size or less are formed in the partition plate.

### (Supplementary Note 10)

In the filter circuit of Supplementary Note 9 above, the opening of each of the through-holes is circular, and
the opening has a diameter of 4 mm or less.

### (Supplementary Note 11)

In the filter circuit of any one of Supplementary Notes 1 to 10 above, the first coil and the second coil are arranged so that the central axes thereof coincide.

### (Supplementary Note 12)

In the filter circuit of any one of Supplementary Notes 1 to 11 above, the first frequency is higher than 4 MHz,
the second frequency is higher than 100 Hz and equal to or lower than 4 MHz, and
the third frequency is equal to or lower than 100 Hz.

### (Supplementary Note 13)

In the filter circuit of any one of Supplementary Notes 1 to 12 above, the first filter further includes a series resonant circuit connected between the wiring between the conductive member and the second filter and the ground and having a coil and a capacitor connected in series, or a capacitor.

### (Supplementary Note 14)

In the filter circuit of any one of Supplementary Notes 1 to 13 above, the core members are made of ferrite, dust material, permalloy, or cobalt-based amorphous material.

### (Supplementary Note 15)

In the filter circuit of any one of Supplementary Notes 1 to 14 above, the conductive member is a heater configured to control the temperature of the substrate.

### (Supplementary Note 16)

In the filter circuit of any one of Supplementary Notes 1 to 15 above, a plurality of conductive members are provided inside the plasma processing apparatus, and the first coil and the second coil are provided for each of the conductive members.

### (Supplementary Note 17)

In the filter circuit of any one of Supplementary Notes 1 to 15 above, a distributer configured to individually supply the control power to each of the plurality of conductive members provided inside the plasma processing apparatus is provided inside the plasma processing apparatus, and
the control power supplied from the power supplier via the first coil and the second coil is supplied to each of the conductive members by the distributer.

### (Supplementary Note 18)

A plasma processing apparatus includes:
a chamber in which a substrate is processed by plasma generated using power of a first frequency and power of a second frequency lower than the first frequency;
a conductive member provided inside the chamber; and
a filter circuit,
wherein the filter circuit includes a first filter provided in a wiring between the conductive member and a power supplier configured to supply control power, which is power of a third frequency lower than the second frequency or DC power, to the conductive member via the filter circuit, and a second filter provided in the wiring between the first filter and the power supplier,
the first filter includes a first coil connected in series to the wiring and having no core member,
the second filter includes a second coil connected in series to the wiring between the first coil and the power supplier and having core members, and
the second coil includes a conducting wire arranged on a surface of at least one of the core members opposite to a surface of at least one of the core members facing a hollow inner cylinder, at least one of the core members arranged annularly around the hollow inner cylinder so as to surround an outer surface of the hollow inner cylinder.

What is claimed is:

1. A filter circuit provided in a plasma processing apparatus in which a substrate is processed by plasma generated using power of a first frequency and power of a second frequency lower than the first frequency, the filter circuit comprising:
a first filter provided in a wiring between a conductive member provided inside the plasma processing apparatus and a power supplier configured to supply control power, which is power of a third frequency lower than the second frequency or DC power, to the conductive member; and
a second filter provided in the wiring between the first filter and the power supplier,
wherein the first filter includes a first coil connected in series to the wiring and having no core member,
wherein the second filter includes a second coil connected in series to the wiring between the first coil and the power supplier and having core members, and
wherein the second coil includes a conducting wire arranged on a surface of at least one of the core members opposite to a surface of at least one of the core members facing a hollow inner cylinder, the at least one of the core members being arranged annularly around the hollow inner cylinder so as to surround an outer surface of the hollow inner cylinder.

2. The filter circuit of claim 1, wherein the core members are annularly arranged around the hollow inner cylinder,
wherein each of the core members is annular,
wherein each of the core members is annularly arranged around the hollow inner cylinder in a direction in which central axes of the core members intersect an extension direction of the hollow inner cylinder, and
wherein the conducting wire constituting the second coil is arranged inside each of the core members.

3. The filter circuit of claim 2, wherein the core members adjacent to each other are annularly arranged around the hollow inner cylinder with an interval left between the adjacent core members.

4. The filter circuit of claim 1, wherein each of the core members is tubular,
wherein each of the core members is annularly arranged around the hollow inner cylinder in a direction in which central axes of the core members intersect an extension direction of the hollow inner cylinder, and
wherein the wiring between the first filter and the power supplier is arranged inside each of the core members.

5. The filter circuit of claim 4, wherein each of the core members is separable on a plane extending along the central axes of the core members.

6. The filter circuit of claim 1, wherein the core members are annularly arranged around the hollow inner cylinder,
wherein each of the core members is rod-shaped, and
wherein each of the core members is arranged annularly around the hollow inner cylinder in a direction in which a longitudinal direction of the core members is oriented to extend along an extension direction of the hollow inner cylinder.

7. The filter circuit of claim 1, further comprising:
a partition plate formed of a conductive member and provided between the first coil and the second coil,
wherein the partition plate is grounded.

8. The filter circuit of claim 7, wherein the partition plate is provided with a wiring region through which a wiring for connecting the first coil and the second coil passes, and
wherein a shielding member is provided in the wiring region so that a straight path extending from the first coil to the second coil is not formed.

9. The filter circuit of claim 7, wherein a plurality of through-holes each having an opening of a predetermined size or less are formed in the partition plate.

10. The filter circuit of claim 9, wherein the opening of each of the plurality of through-holes is circular, and
wherein the opening has a diameter of 4 mm or less.

11. The filter circuit of claim 1, wherein the first coil and the second coil are arranged so that the central axes of the first coil and the second coil coincide with each other.

12. The filter circuit of claim 1, wherein the first frequency is higher than 4 MHz, the second frequency is higher than 100 Hz and equal to or lower than 4 MHz, and the third frequency is equal to or lower than 100 Hz.

13. The filter circuit of claim 1, wherein the first filter further includes a series resonant circuit connected between the wiring between the conductive member and the second filter and a ground and including a coil and a capacitor connected in series to each other, or a capacitor.

14. The filter circuit of claim 1, wherein the core members are made of ferrite, dust material, permalloy, or cobalt-based amorphous material.

15. The filter circuit of claim 1, wherein the conductive member is a heater configured to control a temperature of the substrate.

16. The filter circuit of claim 1, wherein a plurality of conductive members are provided inside the plasma processing apparatus, and
wherein the first coil and the second coil are provided for each of the plurality of conductive members.

17. The filter circuit of claim 1, wherein a distributer configured to individually supply the control power to each of the plurality of conductive members provided inside the plasma processing apparatus is provided inside the plasma processing apparatus, and
wherein the control power supplied from the power supplier via the first coil and the second coil is supplied to each of the plurality of conductive members by the distributer.

18. A plasma processing apparatus, comprising:
a chamber in which a substrate is processed by plasma generated using power of a first frequency and power of a second frequency lower than the first frequency;
a conductive member provided inside the chamber; and
a filter circuit,
wherein the filter circuit includes a first filter provided in a wiring between the conductive member and a power supplier configured to supply control power, which is power of a third frequency lower than the second frequency or DC power, to the conductive member via the filter circuit, and a second filter provided in the wiring between the first filter and the power supplier,
wherein the first filter includes a first coil connected in series to the wiring and having no core member,
wherein the second filter includes a second coil connected in series to the wiring between the first coil and the power supplier and having core members, and
wherein the second coil includes a conducting wire arranged on a surface of at least one of the core members opposite to a surface of at least one of the core members facing a hollow inner cylinder, at least one of the core members arranged annularly around the hollow inner cylinder so as to surround an outer surface of the hollow inner cylinder.
